(19) United States
(12) Patent Application Publication
(10) Pub. No.: US 2009/0289289 A1
(43) Pub. Date: Nov. 26, 2009

(54) DRAM CELL WITH MAGNETIC CAPACITOR

(75) Inventor: James Chyi LAI, Saint Paul, MN (US)

Correspondence Address: Chih Feng Yeh;BRIAN M. MCINNIS, 12th Floor, Ruttonjee House, 11 Duddell Street, Hong Kong, HK

(73) Assignee: NORTHERN LIGHTS SEMICONDUCTOR CORP., Saint Paul, MN (US)

(21) Appl. No.: 12/486,754

(22) Filed: Jun. 18, 2009

Related U.S. Application Data
(63) Continuation-in-part of application No. 11/868,339, filed on Oct. 5, 2007, now abandoned.

(51) Int. Cl. H01L 27/108

(52) U.S. Cl. 257/296; 257/E27.084

(57) ABSTRACT

A DRAM cell includes a substrate, a transistor, and a magnetic capacitor. The substrate is composed of semiconductor material with a main surface, the transistor is formed at the main surface, and the magnetic capacitor is formed in a metal layer. The magnetic capacitor includes a first magnetic layer, a dielectric layer formed on the surface of the first magnetic layer, and a second magnetic layer formed on the surface of the dielectric layer. The dielectric layer is a non-conductive material and the first magnetic layer and the second magnetic layer are formed by an alloy of CoNiFe.

### RELATED APPLICATIONS

This application is a continuation-in-part of U.S. application Ser. No. 11/868,339, filed Oct. 5, 2007, which is herein incorporated by reference.

### BACKGROUND

1. Field of Invention

The present invention relates to a DRAM cell. More particularly, the present invention relates to a DRAM cell with a magnetic capacitor in the metal layer. We name this new device as “McRAM” (Magnetic Capacitor Random Access Memory).

2. Description of Related Art

A Dynamic Random Access Memory (DRAM) cell including a transistor and a storage capacitor per bit has become the most important storage element in electronic system, especially in computer and communication system. The output voltage of a DRAM cell is proportional to the capacitance value of the storage capacitor of the DRAM cell and, therefore, the storage capacitor must have a satisfactory capacitance value to have stable operation of the cell as the applied voltage is scaled.

Furthermore, in a conventional DRAM cell structure, the capacitor is created in the crystal silicon layer because of the need for higher valued capacitance than is typically obtained in the other layers. Also, the capacitor is typically placed adjacent to the transistor and consumes a relatively large and valuable area on the wafer to obtain the needed capacitance values. This makes a DRAM cell large and affects the size of each bit.

However, the main determinant of a DRAM's cost is the density of the memory cells. The goal is to have small-sized memory cells, which means that more of them can be produced at once from a single silicon wafer. This can improve yield, thus reduces the cost.

There are several types of DRAM memory cells that are already available to increase the density, and these memory cells can be divided according to the structure of the capacitor for storing electric charge for information. For example, a trench-type capacitor is formed by forming a deep trench in a semiconductor substrate without increasing the surface area of the semiconductor substrate. The trench-type capacitor can reduce the size of a DRAM cell, but the manufacturing process is difficult and complicated.

Besides, even though these already available memory cells have high density, it comes with the cost of having to refresh the memory periodically. Additional circuitry is required to read and re-write each bit in the memory. This makes the DRAM circuit more complicated, and this means that the memory was not always available for system use because it may be in a refresh cycle. Furthermore, The additional circuitry detracts from the density. DRAM memories are not scaling to remain competitive because of the high area taken by the capacitors used to store the value of the bit.

For the forgoing reasons, there is a need for a new DRAM cell, so that the density of a DRAM may be increased, the manufacturing process is simplified, and the refresh rate is reduced. Thus the cost of manufacturing is reduced.

### SUMMARY

The present invention is directed to a DRAM cell that satisfies this need of increasing the density of the memory device, simplifying the manufacturing process, and reducing the refresh rate.

In an embodiment, a DRAM cell includes a substrate, a transistor, and a magnetic capacitor. The substrate is composed of semiconductor material with a main surface, the transistor is formed at the main surface, and the magnetic capacitor is formed in a metal layer. The magnetic capacitor includes a first magnetic layer, a dielectric layer formed on the surface of the first magnetic layer, and a second magnetic layer formed on the surface of the is dielectric layer. The dielectric layer is a non-conductive material and the first magnetic layer and the second magnetic layer are formed by an alloy of CoNiFe.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a side cross-sectional view of the DRAM cell according to a first preferred embodiment of this present invention.

FIG. 1A is a schematic diagram to depict the magnetic field to prevent escaping charges from the dielectric layer.

FIG. 2 is a side cross-sectional view of the DRAM cell according to a second preferred embodiment of this present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

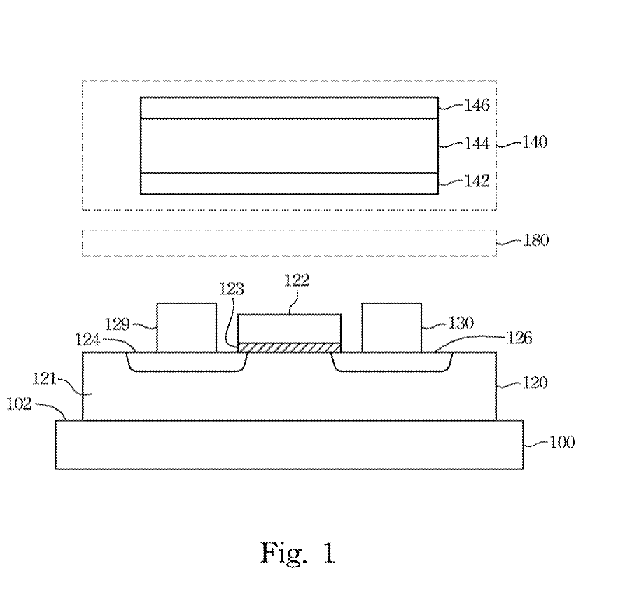

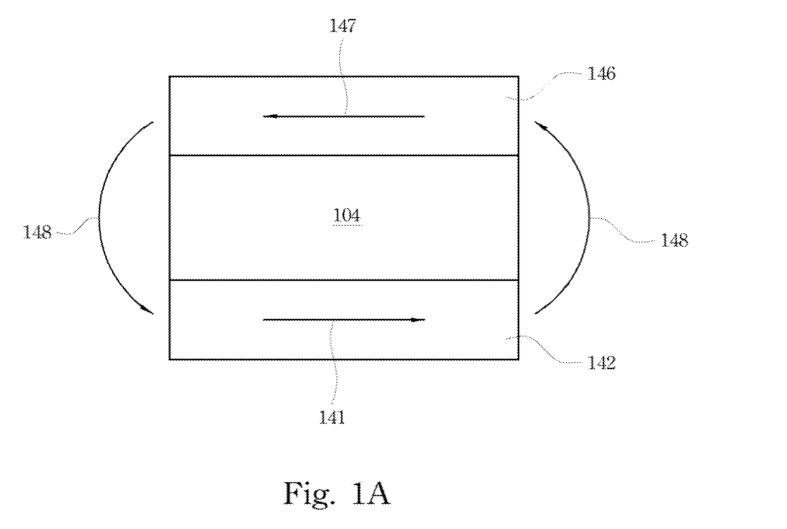

Please refer to FIG. 1. FIG. 1 is a cross-sectional view of the DRAM cell according to a first embodiment of the present invention. A DRAM cell includes a substrate 100, a transistor 120, and a magnetic capacitor 140. We name this new device as “McRAM” (Magnetic Capacitor Random Access Memory. However, in the following paragraph, we still use DRAM to describe this invention. The substrate 100 is composed of semiconductor material with a main surface 102. The transistor 120 includes a source region 124 and a drain region 126 formed at the main surface 102 of the substrate 100. The transistor 120 also includes a control gate 122 placed between the source region 124 and the drain region 126, and separated from the substrate 100 by a thin control dielectric 123. The control gate 122 is polysilicon, and the thin control dielectric 123 may be silicon dioxide.

The capacitor 140 is a magnetic capacitor. The capacitor includes a first magnetic layer 142, a dielectric layer 144 formed on the surface of the first magnetic layer 142, and a second magnetic layer 146 formed on the surface of the dielectric layer 144. The material for forming the dielectric layer 144 is a non-conductive material. In an embodiment, the material for forming the dielectric layer 144 is SiO₂. The material for forming the first magnetic layer 142 and the second magnetic layer 146 is a magnetic material. In an embodiment, the material for forming the first magnetic layer 142 and the second magnetic layer 146 is an alloy of CoNiFe. The distance between the first magnetic layer 142 and the second magnetic layer 146 is larger than 100 Angstrom.

Capacitors are generally governed by this equation (1):

$$C = \frac{{ɛ}_{0} {ɛ}_{k} A}{r} \qquad ( 1 )$$

where C is the capacitance of the capacitor 140, ∈₀ is a constant (approximately 8.85e-12), ∈ₖ is the dielectric constant of the material between the first magnetic layer 142 and the second magnetic layer 146, A is the surface area of the first magnetic layer 142 and the second magnetic layer 146, and r is the distance between the first magnetic layer 142 and the second magnetic layer 146. From the equation (1), if the dielectric constant ∈ₖ of the material between the first magnetic layer 142 and the second magnetic layer 146 increases, the capacitance will increase.

A GMC (Giant Magnetic Capacitance) effect is used to increase the dielectric constant ∈ₖ. GMC acts, figuratively, like a charge trap that brings electrons to closer, thus increasing electron densities between the first magnetic layer 142 and the second magnetic layer 146.

The magnetic field may be provided by the first magnetic layer 142 and the second magnetic layer 146. The magnetic field acts as a force to prevent escaping charges from the dielectric layer 144.

FIG. 1A is a schematic diagram to depict the magnetic field to prevent escaping charges from the dielectric layer. In an embodiment, when the direction of dipole 143 of the first magnetic layer 142 is opposite to that of the dipole 147 of the second magnetic layer 146, the first magnetic layer 142 and the second magnetic layer 146 can generate a magnetic field 148 to prevent escaping charges from the dielectric layer 144. Therefore, the magnetic field 148 provides additional force to increase electron densities between the first magnetic layer 142 and the second magnetic layer 146. Moreover, capacitor leakage and self-discharge are essentially eliminated as electrons are “trapped” in the magnetic field 148.

Thus, with the strong magnetic field, the capacitance is therefore governed by a modified equation:

$$C = \frac{{ɛ}_{0} {ɛ}_{k}^{′} A}{r} \qquad ( 1 )$$

where C is the capacitance of the capacitor 140,

∈₀ is a constant (approximately 8.85e-12),

∈ₖ′=∈ₖ×f where f is a modified factor, the GMC effect factor (˜10⁶-10¹²), due to the magnetic field 148,

A is the surface area of the first magnetic layer 142 and the second magnetic layer 146,

r is the distance between the first magnetic layer 142 and the second magnetic layer 146.

In other words, when the magnetic field 148 is increased, the capacitance is therefore increased. In an embodiment, each of the first magnetic layer 142 and the second magnetic layer 146 is made up multiple thin film deposited layers each about 1 nm thick. Therefore, the magnetic field 148 is increased by increasing the thin film deposited layers forming the first magnetic layer 142 and the second magnetic layer 146. That is that the magnetic field 148 is increased by forming additional thin film deposited layer over the original first magnetic layer 142 and the second magnetic layer 146

It is noted that the symbols [symbol] are arranged to represent the dipoles of the magnetic sections. The symbols [symbol] are not arranged to restrict the dipole directions.

The following table compares the capacitance of a magnetic capacitor with that of a conventional capacitor.

| | Magnetic capacitor | Magnetic capacitor |
|---|---|---|
| | #1 | #2 |
| Mcap capacitance measured | 1.2 nF (at 1 kHz) | 96 uF (at 1 kHz) |
| (Average) | | |
| GMC factor (f) (Average) | 2.0 × 10⁶ | 1.6 × 10¹¹ |
| Conventional capacitance* | 0.6 fF (at k = 3.4) | 0.6 fF (at k = 3.4) |
| (i.e. no GMC effect) | | |

$\begin{matrix}\text{*} Conventional Capacitance = \frac{8.85 \times {10}^{- 12} \times 3.4 \times 1.6 \times {10}^{- 6} \times 0.55 \times {10}^{- 6}}{50 \times {10}^{- 9}} \\ = 5.9 \times {10}^{- 16} F \\ = 0.6 fF\end{matrix}$

Because of the f factor, GMC effect factor (˜10⁶-10¹²), from the magnetic field generated by the first magnetic layer 142 and the second magnetic layer 146, the capacitance of the magnetic capacitor is significantly higher the conventional capacitor.

Notice that the capacitor 140 is formed in the metal layer above the transistor 120. Conventional capacitors are created in the crystal silicon layer to obtain higher valued capacitance; however, modern capacitors are capable of obtaining the needed DRAM capacitance values when they are created in the metal layer. As a result, the magnetic capacitor 140 can be formed above the transistor 120 in the metal layer 160. However, the magnetic capacitor 140 does not need to be created directly above the transistor 120. When the magnetic capacitor 140 is moved from the crystal silicon layer to the metal layer 160, the overall area of the DRAM cell can be significantly reduced. Besides, the necessary wiring connections for the DRAM cell can be placed in a routing area 180, located in between the transistor 120 and the magnetic capacitor 140, to achieve greater intensity.

With the magnetic capacitor 140 formed in the metal layer of semiconductors, it is now possible to reduce or eliminate the DRAM refresh rate. The magnetic capacitor 140 can store the information just like a standard capacitor, but has low to no leakage and high valued capacitance. Because of low to no leakage, the refresh rate is reduced to allow more time for system operation. The leakage may be so low as to eliminate the refresh altogether. This allows the removal of the refresh circuitry. Additionally, with no refresh, this memory maintains its values even after the power is removed. As a result, this invention turns DRAM into non-volatile memory, and can be used to replace Flash memories. Besides, the magnetic capacitor 140 is radiation hard in environments with high levels of radiation. This is because the energy needed to upset the magnetic capacitor 140 must be much higher than most radiation specifications to upset a bit. However, the capacitance the magnetic capacitor 140 stored to maintain memory is high enough to withstand significant radiation from environments, thus the magnetic capacitor 140 is radiation hard.

Furthermore, the capacitance values of modern capacitors have increased dramatically, with dielectric constants over 3000, thinner dielectrics, and surface roughness. This allows that the magnetic capacitor 140 can take up less space than the transistor 120. Note that even though the gate length of the transistor 120 is very small, the magnetic capacitor 140 has the area for the entire transistor 120, including contacts 129 and 130, the control gate 122 and a diffusion area 121.

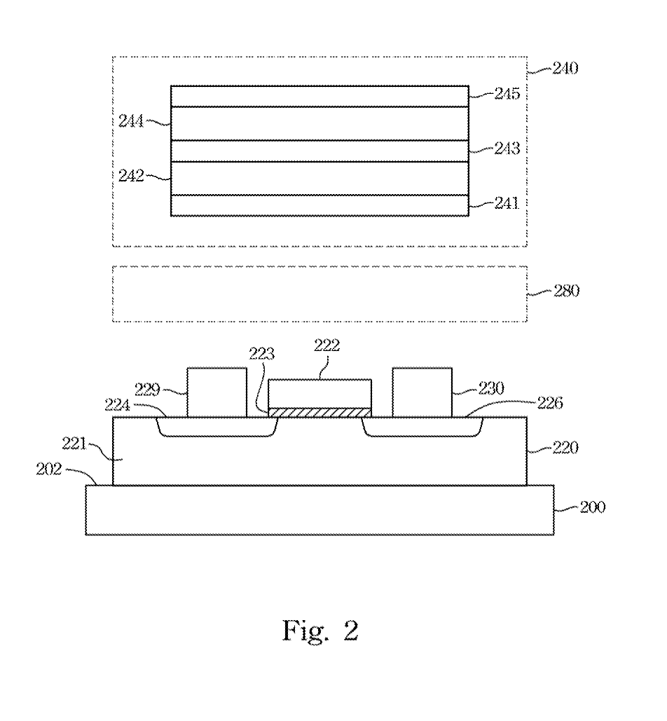

Please refer to FIG. 2, a cross-sectional view of the DRAM cell according to a second preferred embodiment of this present invention. A DRAM cell includes a substrate 200, a transistor 220, and a magnetic capacitor 240. The substrate 200 is composed of semiconductor material with a main surface 202. The transistor 220 includes a source region 224 and a drain region 226 formed at the main surface 202 of the substrate 200. The transistor 220 also includes a control gate 222 placed between the source region 224 and the drain region 226, and separated from the substrate 200 by a thin control dielectric 223. The control gate 222 is polysilicon, and the thin control dielectric 223 may be silicon dioxide.

Modern capacitors are capable of obtaining the needed DRAM capacitance values when they are created in the metal layer. As a result, the magnetic capacitor 240 can be formed above the transistor 220. However, the magnetic capacitor 240 does not need to be created directly above the transistor 220. When the magnetic capacitor 240 is created in the metal layer, the overall area of the DRAM cell can be significantly reduced.

Notice that the capacitor 240 is built in multiple layers with the first magnetic layer 241, the third magnetic layer 243, and the fifth magnetic layer 245. When the capacitor does not provide sufficient capacitance with a single layer of capacitance, multiple layers can be placed to provide the desired capacitance. In addition, this invention allows for scaling to smaller dimensions because the capacitor size relative to the transistor size remains about the same. As the size of the transistor gets smaller, the amount of current it can handle also gets smaller. That is when the DRAM cell requires larger amount of capacitance relative to the size of the transistor. The capacitor can be built with multiple layers to provide the additional capacitance. So, in this second embodiment, the first magnetic layer 241, the third magnetic layer 243, and the fifth magnetic layer 245 are placed to provide the desired capacitance for the transistor 220.

Besides, the necessary wiring connections for the DRAM cell can be placed in a routing area 280, located in between the transistor 220 and the magnetic capacitor 240, to achieve greater intensity. Lastly, the capacitance values of modern capacitors have increased dramatically, with dielectric constants over 3000, thinner dielectrics, and surface roughness. This allows that the magnetic capacitor 240 takes up less space than the transistor 220. Note that even though the gate length of the transistor 220 is very small, the magnetic capacitor 240 has the area for the entire transistor 220, including contacts 229 and 230, the control gate 222 and a diffusion area 221.

The difference between the first and the second embodiment is that the capacitor in the second embodiment is built with multiple layers to provide the desired capacitance when the invention scales to small dimensions or one single layer does not provide sufficient capacitance.

Moreover, since the magnetic capacitor still can retain the electric charge when the power supplied to the magnetic capacitor is off, the DRAM become as Non-Volatile memory likes NAND and NOR flash when the magnetic capacitor into Dram structure.

From the description above, we can conclude that this invention of a small-sized DRAM cell satisfies the need of increasing the density of the DRAM cells, thus lowers the cost of fabrication. The small-sized DRAM cell is achieved by creating the magnetic capacitor in the metal layer, and has the capability of increasing the speed of DRAM integrated circuits and reducing the power consumed by DRAM integrated circuits. Because of the improved speed, this memory cell can be used to replace SRAM. Furthermore, the magnetic capacitor has low to no leakage, so DRAM refresh rate can be reduced or eliminated. When DRAM refresh rate is eliminated, the refresh circuitry can be removed, and the DRAM cell becomes non-volatile. Therefore, this invention can replace other standard electronic forms of memory. Besides, the magnetic capacitor is radiation hard in environments with high levels of radiation.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A DRAM cell, comprising:
a substrate having semiconductor material with a main surface;
a transistor formed at the main surface; and
a magnetic capacitor formed in a metal layer located above the transistor, wherein the magnetic capacitor includes:
a first magnetic layer;
a dielectric layer formed on the surface of the first magnetic layer; and
a second magnetic layer formed on the surface of the dielectric layer, wherein the dielectric layer is a non-conductive material and the first magnetic layer and the second magnetic layer are formed by an alloy of CoNiFe.

2. The DRAM cell of claim 1, wherein the transistor includes:
a source region;
a drain region; and
a control gate placed between the source region and the drain region and separated from the substrate by a thin control dielectric.

3. The DRAM cell of claim 1, wherein a direction of dipole of the first magnetic layer is opposite to that of dipole of the second magnetic layer.

4. The DRAM cell of claim 1, wherein a distance between the first magnetic layer and the second magnetic layer is larger than 100 Angstrom.

5. The DRAM cell of claim 1, wherein the first magnetic layer and the second magnetic layer generate a GMC (Giant Magnetic Capacitance) effect.

6. The DRAM cell of claim 1, wherein the first magnetic layer is made up multiple thin film deposited layers.

7. The DRAM cell of claim 6, wherein each thin film deposited layer is about 1 nm thick.

8. The DRAM cell of claim 1, wherein the second magnetic layer is made up multiple thin film deposited layers.

9. The DRAM cell of claim 8, wherein the each thin film deposited layer is about 1 nm thick.

10. The DRAM cell of claim 1, further comprising a routing area between the transistor and the magnetic capacitor for the wiring connections of the DRAM cell.

11. A DRAM cell, comprising:
a substrate having semiconductor material with a main surface;
a transistor formed at the main surface; and
a magnetic capacitor formed in a plurality of layers located above the transistor, wherein the magnetic capacitor includes:
a plurality of magnetic layers; and
a plurality of dielectric layers;
wherein the plurality of dielectric layers are formed between the plurality of magnetic layers, wherein the dielectric layer is a non-conductive material and the magnetic layers are formed by an alloy of CoNiFe.

12. The DRAM cell of claim 11, wherein the transistor includes:
a source region;
a drain region; and
a control gate placed between the source region and the drain region and separated from the substrate by a thin control dielectric.

13. The DRAM cell of claim 11, wherein each of the magnetic layers is made up multiple thin film deposited layers.

14. The DRAM cell of claim 13, wherein each thin film deposited layer is about 1 nm thick.
